(19) United States
(12) Patent Application Publication
(10) Pub. No.: US 2023/0369446 A1
(43) Pub. Date: Nov. 16, 2023

(54) METHOD FOR MANUFACTURING SEMICONDUCTOR STRUCTURE

(71) Applicant: ENKRIS SEMICONDUCTOR, INC., Suzhou, Jiangsu (CN)

(72) Inventor: Kai CHENG, Suzhou, Jiangsu (CN)

(73) Assignee: ENKRIS SEMICONDUCTOR, INC., Suzhou, Jiangsu (CN)

(21) Appl. No.: 18/030,048

(22) PCT Filed: Nov. 13, 2020
(86) PCT No.: PCT/CN2020/128771

§ 371 Date: Apr. 3, 2023

(51) Int. Cl. H01L 29/66

(52) U.S. Cl. CPC H01L 29/66462

(57) ABSTRACT

The present disclosure provides a method for manufacturing a semiconductor structure, the mothed including: providing a substrate, a heterojunction structure, and a P-type semiconductor layer, which are distributed from bottom to top; forming a patterned mask layer on the P-type semiconductor layer, the patterned mask layer covering at least a portion of the P-type semiconductor layer in a gate region; removing an exposed portion of the P-type semiconductor layer by in-situ etching with a corrosive gas, by using the patterned mask layer as a mask; and then activating the P-type dopant ions in the P-type semiconductor layer.

### CROSS REFERENCE TO RELATED APPLICATIONS

This application is a U.S. National Phase of a PCT Application No. PCT/CN2020/128771 filed on Nov. 13, 2020, the entire contents of which are incorporated herein by reference in their entireties.

### TECHNICAL FIELD

This present application relates to the field of semiconductor, and more particular, to a method for manufacturing a semiconductor structure.

### BACKGROUND

As a typical representative of the third-generation semiconductor materials, the wide band semiconductor materials group III nitrides have excellent characteristics of wide bandgap, high voltage resistance, high temperature resistance, high electron saturation velocity and drift velocity, and easiness to form high-quality heterostructure, and thus are very suitable for manufacturing high temperature, high frequency, and high power electronic devices.

For example, due to strong spontaneous polarization and piezoelectric polarization of AlGaN/GaN heterojunction, there is a high concentration of two-dimensional electron gas (2DEG) at the AlGaN/GaN interface, and thus AlGaN/GaN heterojunction is widely used in semiconductor structures such as High Electron Mobility Transistor (HEMT).

Enhanced devices are widely applied in the field of power electronics due to their often-off characteristics. There are various ways to implement enhanced devices, such as depleting the two-dimensional electron gas by placing a P-type semiconductor layer at a gate region.

However, when the P-type semiconductor layer outside the gate region is removed by etching, the etching needs to be performed in an etching chamber. The semiconductor manufacturing process includes multiple transfers between chambers, which increases the risk of contamination and leads to low production efficiency.

In view of this, it is necessary to provide a new method for manufacturing a semiconductor structure so as to solve the above technical problems.

### SUMMARY

The object of the present disclosure is to provide a method for manufacturing a semiconductor structure to reduce the risk of contamination and improve production efficiency.

To achieve the above purpose, the present disclosure provides a method for manufacturing a semiconductor structure, the method includes:
providing a substrate, a heterojunction structure, and a P-type semiconductor layer, which are distributed from bottom to up;
forming a patterned mask layer on the P-type semiconductor layer, where the patterned mask layer at least covers a portion of the P-type semiconductor layer in the gate region; removing an exposed portion of the P-type semiconductor layer by in-situ etching with a corrosive gas, by using the patterned mask layer as a mask;
activating P-type dopant ions in the P-type semiconductor layer.

Optionally, the in-situ etching includes: a step of forming a patterned mask layer and a step of etching, which are performed in one reaction chamber or in different chambers of one vacuum interconnect device.

Optionally, a material of the P-type semiconductor layer is GaN, removing the exposed portion of the P-type semiconductor layer by in-situ etching is performed at a temperature higher than 300° C., and the corrosive gas includes H₂ and/or NH₃, a mixture of Cl₂ and N₂, or HCl.

Optionally, removing the exposed portion of the P-type semiconductor layer by in-situ etching is performed at a temperature higher than 700° C.

Optionally, before activating P-type dopant ions in the P-type semiconductor layer, the patterned mask layer is removed to expose the portion of the P-type semiconductor layer in the gate region.

Optionally, after activating P-type dopant ions in the P-type semiconductor layer, an N-type semiconductor layer is grown on two sides of the P-type semiconductor layer and on the heterojunction structure, by using the patterned mask layer as a mask.

Optionally, a material of the N-type semiconductor layer is GaN or AlGaN.

Optionally, after activating P-type dopant ions in the P-type semiconductor layer, an N-type semiconductor layer is grown on top of the patterned mask layer, on two sides of the patterned mask layer and the P-type semiconductor layer, and on the heterojunction structure.

Optionally, a material of the N-type semiconductor layer is AlN.

Optionally, a material of the heterojunction structure adjacent to the P-type semiconductor layer is AlGaN.

Optionally, after removing an exposed portion of the P-type semiconductor layer by in-situ etching, a step of cooling down is performed; and supplying the corrosive gas is stopped in the step of cooling down.

Optionally, in the step of cooling down, supplying the corrosive gas is stopped at a temperature greater than or equal to 600° C.

Optionally, in the step of cooling down, an inert protective gases is provided.

Optionally, activating P-type dopant ions in the P-type semiconductor layer is achieved by annealing at a temperature greater than 500° C.

Optionally, a material of the patterned mask layer is silicon dioxide, silicon nitride or silicon oxynitride.

Optionally, the method for manufacturing further includes: forming a source electrode on a source region, a drain electrode on a drain region, and a gate electrode on an activated P-type semiconductor layer.

Compared with the prior art, the present disclosure has the following beneficial effects:
(1) When the P-type semiconductor layer on the heterojunction structure is patterned, the P-type semiconductor layer made of some materials may react with a targeted corrosive gas to complete the etching removal, so that etching the P-type semiconductor layer may be achieved by injecting a corrosive gas into the process chamber of the previous step, that is, the etching is in-situ treatment. The advantage includes that a transfer process between chambers when etching may be avoided, a risk of contamination is avoided, and a production efficiency is improved.
2) In an optional embodiment, a material of the P-type semiconductor layer is GaN, and a corrosive gas includes H₂ and/or NH₃. H₂ may react with solid GaN material at high temperature to produce gaseous Ga and NH₃; NH₃ may catalyze solid GaN material to gaseous GaN material. H₂ and/or NH₃ reacts completely with solid GaN material and does not corrode other materials, for example, the patterned mask layer and the heterojunction structure are not corroded. Therefore, when the P-type semiconductor layer is patterned, the etching selectively is good and the etching damage to the heterojunction structure is not generated.
3) In an optional embodiment, when the P-type dopant ions in the P-type semiconductor layer are activated, the P-type semiconductor layer is covered with a patterned mask layer, and the material of the patterned mask layer is silicon dioxide. Oxygen ions in the silicon dioxide may adsorb H ions in the P-type semiconductor layer, such that the H ions are released to the outside via the surface. Thus, the release velocity of H ions may be accelerated during the process of activating the P-type semiconductor layer.
4) In an optional embodiment, after a step of the activating P-type dopant ions in the P-type semiconductor layer, an N-type semiconductor layer is grown on two sides of the P-type semiconductor layer and on the heterojunction structure, by using the patterned mask layer as a mask. The N-type semiconductor layer may provide electron carriers to the heterojunction structure, thereby reducing the resistance between the source electrode and the drain electrode while the source electrode and the drain electrode are connected with each other. The N-type semiconductor layer may be made by doping the semiconductor layer with N-type elements, or may be an unintentionally doped semiconductor layer.
5) In an optional embodiment, after a step of the activating P-type dopant ions in the P-type semiconductor layer, an N-type semiconductor layer is grown on top of the patterned mask layer, on two sides of the patterned mask layer and the P-type semiconductor layer, and on the heterojunction structure. The difference with the optional embodiment 4) is that whether N-type semiconductor layer can grow on the patterned mask layer may be determined by selecting the specific material of the N-type semiconductor layer.
6) In an optional embodiment, after a step of removing the exposed portion of the P-type semiconductor layer by in-situ etching, a step of cooling down is performed, and supplying the corrosive gas is stopped in the step of cooling down. H ions may be bond to the P-type dopant ions (e.g., Mg ions), that is, the P-type doped ions may be passivated, so that holes may not be generated. Therefore, stopping the supply of H₂ and NH₃ can prevent the P-type dopant ions from being passivated.

### BRIEF DESCRIPTION OF THE DRAWINGS

FIG. 1 is a flowchart of a method for manufacturing a semiconductor structure according to a first embodiment of the present disclosure;

FIGS. 2 and 3 are schematic diagrams illustrating intermediate structures corresponding to process in FIG. 1;

FIG. 4 is a schematic diagram of an intermediate structure corresponding to a method for manufacturing a semiconductor structure according to a second embodiment of the present disclosure.

FIG. 5 is a schematic diagram of an intermediate structure corresponding to a method for manufacturing a semiconductor structure according to a third embodiment of the present disclosure.

FIG. 6 is a schematic diagram of an intermediate structure corresponding to a method for manufacturing a semiconductor structure according to a fourth embodiment of the present disclosure.

FIG. 7 is a schematic diagram of an intermediate structure corresponding to a method for manufacturing a semiconductor structure according to a fifth embodiment of the present disclosure.

FIG. 8 is a schematic diagram of an intermediate structure corresponding to a method for manufacturing a semiconductor structure according to a sixth embodiment of the present disclosure.

FIGS. 9 and 10 are schematic diagrams of intermediate structures corresponding to a method for manufacturing a semiconductor structure according to a seventh embodiment of the present disclosure.

In order to facilitate the understanding of the present disclosure, all reference signs appearing in the present disclosure are listed below:
Substrate 10
Heterojunction structure 11
Channel layer 111
Potential barrier layer 112
Gate region 11a
Source region 11b
Drain region 11c
P-type semiconductor layer 12
Patterned mask layer 13
N-type semiconductor layer 14
Gate electrode 15a
Source electrode 15b
Drain electrode 15c

### DETAILED DESCRIPTION OF THE EMBODIMENTS

In order to make the above-mentioned purposes, features and advantages of the present disclosure more apparent and understandable, specific embodiments of the present disclosure will be described in detail below with reference to the accompanying drawings.

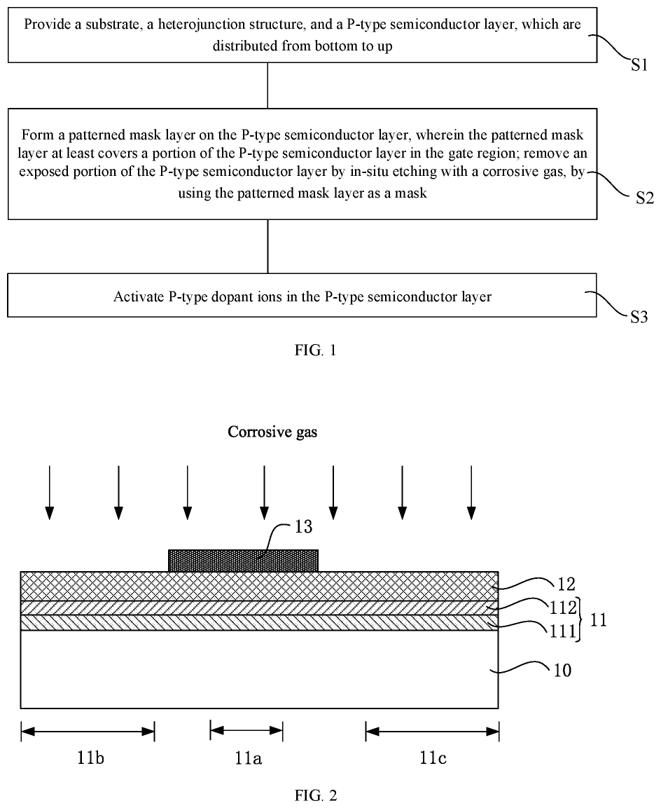

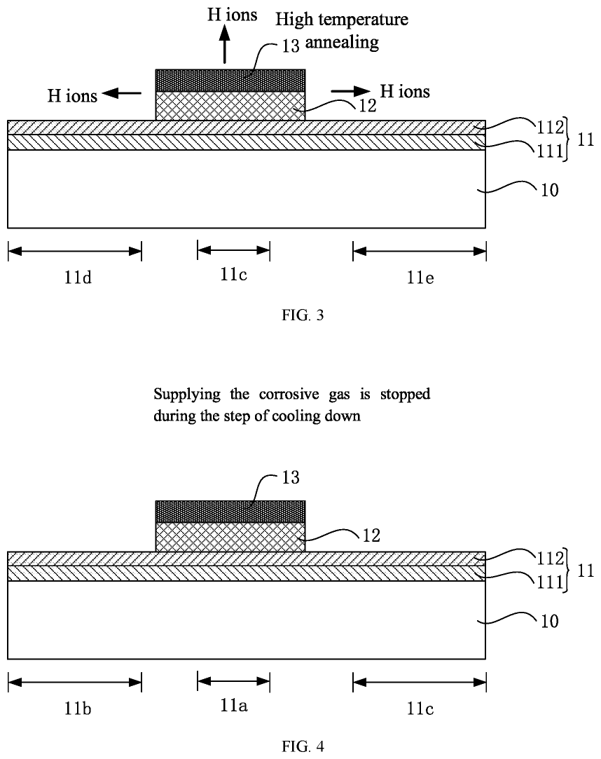

FIG. 1 is a flowchart of a method for manufacturing a semiconductor structure according to a first embodiment of the present disclosure; and FIGS. 2 and 3 are schematic diagrams illustrating intermediate structures corresponding to the process of FIG. 1.

Firstly, referring to step S1 in FIG. 1 and FIG. 2, a substrate 10, a heterojunction structure 11, and a P-type semiconductor layer 12, which are distributed from bottom to up are provided.

A material of the substrate 10 may be sapphire, silicon carbide, silicon, silicon on insulator (SOI), lithium niobate, GaN, AN, or diamond.

The heterojunction structure 11 may include a group III nitride material.

In this embodiment, the heterojunction structure 11 includes a channel layer 111 and a potential barrier layer 112, which are distributed from bottom to up. A two-dimensional electron gas may be formed at an interface of the channel layer 111 and the potential barrier layer 112. Materials of the channel layer 111 and the potential barrier layer 112 may be group III nitride materials. In an optional embodiment, the channel layer 111 is an intrinsic GaN layer and the potential barrier layer 112 is an N-type AlGaN layer. N-type ions may be at least one of Si ions, Ge ions, Sn ions, Se ions, and Te ions. In other optional embodiments, the materials combination of the channel layer 111 and the potential barrier layer 112 may also be GaN/AlN, GaN/InN, GaN/InAlGaN, GaAs/AlGaAs, GaN/InAlN, or InN/InAlN. Furthermore, in addition to having one layer respectively, the channel layer 111 and the potential barrier layer 112 shown in FIG. 2 may also have multiple layers respectively, which are distributed alternately; or the channel layer 111 has one layer and the potential barrier layer 112 has multiple layers to form a multi-barrier structure.

The epitaxial growth processes of the channel layer 111 and the potential barrier layer 112 can include: Atomic Layer Deposition (ALD), or Chemical Vapor Deposition (CVD), or molecular beam epitaxial (MBE), or Plasma Enhanced Chemical Vapor Deposition (PECVD), or Low Pressure Chemical Vapor Deposition (LPCVD), or Metal-Organic Chemical Vapor Deposition (MOCVD), or a combination thereof

In some embodiments, the heterojunction structure 11 includes a back barrier layer and a channel layer, which are distributed from bottom to up.

The heterojunction structure 11 includes a gate region 11a, and a source region 11b and a drain region 11c at both sides of the gate region 11a respectively. The gate region 11 a is used to form a gate electrode, the source region 11b is used to form a source electrode, and the drain region 11c is used to form a drain electrode.

A nucleation layer and a buffer layer (not shown) distributed from bottom to up may be also placed between heterojunction structure 11 and the substrate 10, a material of the nucleation layer may be, for example, AlN, AlGaN, and etc., and a material of the buffer layer may include at least one of AIN, GaN, AlGaN, or AlInGaN. The nucleation layer may alleviate the problem of lattice mismatch and thermal mismatch between the epitaxially grown semiconductor layers, such as the channel layer 111 in the heterojunction structure 11 and the substrate 10, and the buffer layer may reduce the dislocation density and the defect density of the epitaxially grown semiconductor layer and may improve the crystal quality.

The material of the P-type semiconductor layer 12 is a group III-V compound. In this embodiment, the P-type semiconductor layer 12 is specifically GaN. In other embodiments, it may be other materials.

The epitaxial growth of the P-type semiconductor layer 12 may refer to the epitaxial growth of the channel layer 111 and the potential barrier layer 112. The P-type dopant ions may be at least one of Mg ions, Zn ions, Ca ions, Sr ions, or Ba ions to deplete a two-dimensional electron gas below the gate region to form an enhanced device. The P-type dopant ions in the P-type semiconductor layer 12 may be achieved by in-situ doping.

In some embodiments, the substrate 10, the heterojunction structure 11, and the P-type semiconductor layer 12, which are distributed from bottom to up in step S1 may also be an existing pre-final structure.

Secondly, referring to step S2 in FIG. 1 and FIG. 2, a patterned mask layer 13 is formed on the P-type semiconductor layer 12, where the patterned mask layer 13 at least covers a portion of the P-type semiconductor layer 12 in the gate region 11a. Referring to FIGS. 2 and 3, the patterned mask layer 13 is used as a mask, and an exposed portion of the P-type semiconductor layer 12 is removed by in-situ etching with a corrosive gas.

The material of the mask layer 13 may be silicon dioxide, silicon nitride or silicon oxynitride, and may be formed by physical vapor deposition (PVD), chemical vapor deposition (CVD), plasma enhanced chemical vapor deposition (PECVD), low pressure chemical evaporation deposition (LPCVD) or atomic layer deposition (ALD) accordingly. The patterning may be achieved by dry etching or wet etching. Referring to FIG. 2, in this embodiment, the size of the patterned mask layer 13 is slightly larger than the size of the gate region 11 a.

In this embodiment, the material of the P-type semiconductor layer 12 is GaN, and the corresponding corrosive gas includes H₂ and/or NH₃.

At high temperature, for example, at a temperature greater than 300° C., the chemical equation for the reaction of H₂ with the exposed portion of P-type semiconductor layer 12 is:

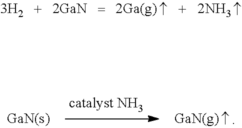

At high temperature, for example, at a temperature greater than 300° C., the chemical equation for the reaction of NH₃ with the exposed portion of P-type semiconductor layer 12 is:

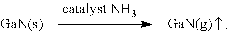

The above reaction is preferably performed at 700° C. or higher.

The etching of the above P-type semiconductor layer 12 is dry etching. The dry etching may be inductively coupled plasma etching (ICP).

Since a material of the P-type semiconductor layer 12 is GaN, which may react with the targeted corrosive gas H₂ and/or NH₃ to complete the etching removal. Therefore, the P-type semiconductor layer 12 may be etched in-situ by injecting the corrosive gas into a process chamber of a previous step. The advantage includes that: a transfer process between the chambers when etching may be avoided, a risk of contamination is avoided, and a production efficiency is improved. The process chamber of the previous step may include the chamber where the mask layer 13 is formed and patterned, and may also include the chamber where the heterojunction structure 11 and the P-type semiconductor layer 12 are epitaxially grown.

In other embodiments, the process chamber of the previous step and the chamber for etching may also be different chambers of one vacuum interconnect device.

The corrosive gas such as H₂ and/or NH₃ do not react with the patterned mask layer 13, and thus the etch selectivity is good when the P-type semiconductor layer 12 is patterned. In addition, by selecting the material of the potential barrier layer 112, the potential barrier layer 112 cannot react with the corrosive gas such as H₂ and/or NH₃. The potential barrier layer 112 may be used as an etch stop layer for the process of patterning the P-type semiconductor layer 12 without causing etch damage to the heterojunction structure 11.

In some embodiments, the corrosive gas may also be a mixture gas of Cl₂ and N₂, or HCl. In the mixture gas of Cl₂ and N₂, the amount of substance of Cl₂ is preferably less than 10% of the total amount of substance of the corrosive gas.

Afterwards, referring to step S3 in FIG. 1 and FIG. 3, P-type dopant ions in the P-type semiconductor layer is activated.

A large amount of H ions is present in the process environment where the P-type semiconductor layer 12 is grown, such as the MOCVD growth environment. If the H ions are not removed, the P-type dopant ions (acceptor dopant, such as Mg ions) in the group III nitride materials may bond with the H ions, so as to be passivated by a large amount of H ions without generating cavities.

Activating the P-type dopant ions in the P-type semiconductor layer 12 may be achieved by high temperature annealing, e.g., at a temperature greater than 500° C., to allow the H ions to escape. In some embodiments, high-temperature annealing is performed in an inactive gas to prevent the introduction of H ions. For example, the P-type dopant ions may be activated in a hydrogen-free gas atmosphere such as nitrogen, a mixture of nitrogen and oxygen, laughing gas (NO), or argon and etc. During high-temperature annealing, nitrogen molecules and decomposition products of nitrogen molecules may effectively penetrate into the surface of the group III nitride materials, nitrogen vacancy caused during etching are well compensated, and the quality of the P-type semiconductor layer 12 may be improved.

Activating the P-type dopant ions in the P-type semiconductor layer 12 may also be an in-situ treatment, i.e., which is performed in the same chamber as step S2.

Referring to FIG. 3, when activating the P-type dopant ions in the P-type semiconductor layer 12, the P-type semiconductor layer 12 is covered by the patterned mask layer 13. When a material of the patterned mask layer 13 is silicon dioxide, oxygen ions in the silicon dioxide may adsorb H ions in the P-type semiconductor layer 12, such that H ions are released to the outside via the surface. Thus, the release velocity of H ions in the P-type semiconductor layer 12 may be accelerated.

FIG. 4 is a schematic diagram of an intermediate structure corresponding to a method for manufacturing a semiconductor structure according to a second embodiment of the present disclosure. Referring to FIG. 4, a manufacturing method of the semiconductor structure of this second embodiment is substantially the same as the manufacturing method of the semiconductor structure of first embodiment, and the different includes that: between the step S2 and the step S3, a step of cooling down is performed, and supplying the corrosive gas is stopped during the step of cooling down.

The advantage includes that the P-type dopant ions in the P-type semiconductor layer 12 may be prevented from combining with the H ions in the corrosive gas and being passivated.

Optionally, in the step of cooling down, supplying the corrosive gas is stopped at a temperature greater than or equal to 600° C.

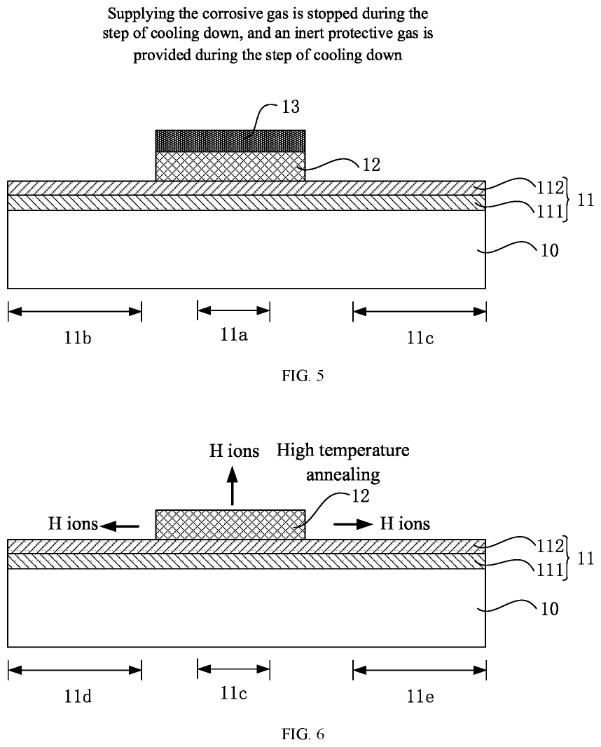

FIG. 5 is a schematic diagram of an intermediate structure corresponding to a method of manufacturing nitride semiconductor substrate according to a third embodiment of the present disclosure. Referring to FIG. 5, a manufacturing method of the semiconductor structure of this third embodiment is substantially the same as the manufacturing method of the semiconductor structure of the second embodiment, and the different includes that: an inert protective gas is provided during the step of cooling down. The inert protective gas may include nitrogen or argon. The inert protective gas may prevent the P-type semiconductor layer 12 from being oxidized.

FIG. 6 is a schematic diagram of an intermediate structure corresponding to a method of manufacturing nitride semiconductor substrate according to a fourth embodiment of the present disclosure. Referring to FIG. 6, a manufacturing method of the semiconductor structure of this fourth embodiment is substantially the same as the manufacturing methods of the semiconductor structure of the first embodiment to the third embodiment, and the different includes that: at step S3, before activating P-type dopant ions in the P-type semiconductor layer 12, the patterned mask layer 13 is removed to expose the portion of P-type semiconductor layer 12 in the gate region 11a.

The P-type semiconductor layer 12 in the gate region 11a is exposed, such that H ions may also be released from the top surface of the P-type semiconductor layer 12 to the outside.

FIG. 7 is a schematic diagram of an intermediate structure corresponding to a method for manufacturing a semiconductor structure according to a fifth embodiment of the present disclosure. Referring to FIG. 7, the manufacturing method of the semiconductor structure of this fifth embodiment is substantially the same as the manufacturing method of the semiconductor structure of the first embodiment to the fourth embodiment, and the different includes that: the method for manufacturing a semiconductor structure provided by the fifth embodiment further includes a step S4. At step S4, by using patterned mask layer 13 as a mask, an N-type semiconductor layer 14 is grown on two sides of the P-type semiconductor layer 12 and the heterojunction structure 11.

A material of the N-type semiconductor layer 14 is a group III-V compound, which, may be for example GaN or AlGaN, and the above materials are difficult to grow on the patterned mask layer 13. The percentage of amount of substance of Al in the AlGaN material is preferably less than 10%. The N-type semiconductor layer 14 may be achieved by doping N-type ions within a III-V compound, the N-type ions may be at least one of Si ions, Ge ions, Sn ions, Se ions or Te ions. The material of the N-type semiconductor layer 14 may also be an unintentionally doped III-V compound due to the presence of Si ions in the epitaxial growth environment.

The N-type semiconductor layer may provide electron carriers to the heterojunction structure, thereby reducing a resistance between the source electrode and the drain electrode while the source electrode and the drain electrode are connected with each other.

Afterwards, the patterned mask layer 13 may be removed to expose the P-type semiconductor layer 12. The patterned mask layer 13 may be removed by wet etching.

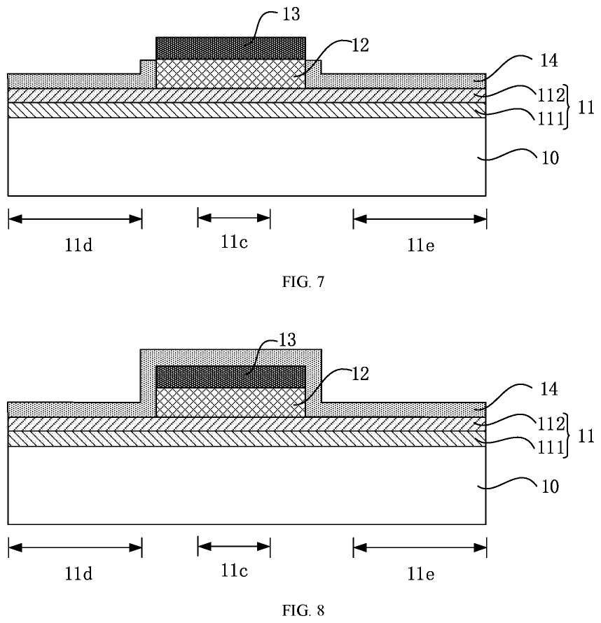

FIG. 8 is a schematic diagram of an intermediate structure corresponding to a method for manufacturing a semiconductor structure according to a sixth embodiment of the present disclosure. Referring to FIG. 8, a manufacturing method of the semiconductor structure of this sixth embodiment is substantially the same as the manufacturing method of the semiconductor structure of the fifth embodiment, and the different includes that: at step S4, the N-type semiconductor layer 14 is also grown on the top and two sides of the patterned mask layer 13.

The material of N-type semiconductor layer 14 may be, for example, AlN, which may be grown on the patterned mask layer 13.

Afterwards, the patterned mask layer 13 and the N-type semiconductor layer 14 on the patterned mask layer 13 may be removed to expose the P-type semiconductor layer 12. The patterned mask layer 13 and the N-type semiconductor layer 14 on the patterned mask layer 13 may be removed by dry etching.

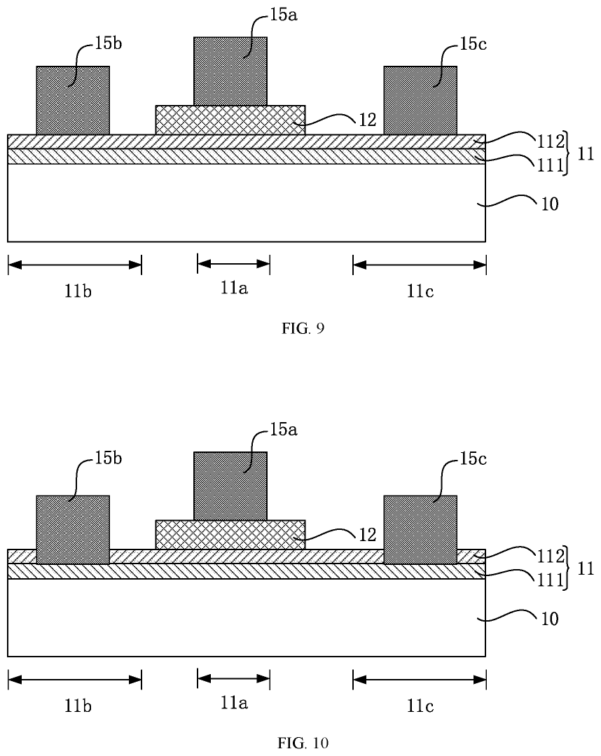

FIGS. 9 and 10 are schematic diagrams of intermediate structures corresponding to the method for manufacturing a semiconductor structure according to the seventh embodiment of the present disclosure. Referring to FIGS. 9 and 10, the manufacturing method of the semiconductor structure of this seventh embodiment is substantially the same as the manufacturing method of the semiconductor structure of the first embodiment to the sixth embodiment, except that after step S4 (or after step S3 if step S4 is not performed), the source electrode 15b is formed on the source region 11b, the drain electrode 15c is formed on the drain region 11c, and the gate electrode 15a is formed on the activated P-type semiconductor layer 12.

Specifically, a metal layer, such as Ti/Al/Ni/Au, Ni/Au, etc., may be formed first by sputtering; the metal layer outside the gate region 11a, source region 11b, and the drain region 11c are removed by etching, and ohmic contacts between the source electrode 15b and the source region 11b, the drain electrode 15c and the drain region 11c, and the gate electrode 15a and the P-type semiconductor layer 12 in the gate region 11a are formed by high-temperature annealing.

The difference between the method of making the semiconductor structure of FIG. 9 and that of FIG. 10 is that: in FIG. 9, both the source electrode 15b and the drain electrode 15c are in contact with the potential barrier layer 112; in FIG. 10, both the source electrode 15b and the drain electrode 15c are in contact with the channel layer 111.

Although the present disclosure discloses the above contents, the present disclosure is not limited thereto. One of ordinary skill in the art may make various variants and modifications to the present disclosure without departing from the spirit and scope of the present disclosure. Therefore, the protection scope of the present disclosure should be set forth by the appended claims.

1. A method for manufacturing a semiconductor structure, comprising:
providing a substrate, a heterojunction structure, and a P-type semiconductor layer, which are distributed from bottom to up;
forming a patterned mask layer on the P-type semiconductor layer, wherein the patterned mask layer at least covers a portion of the P-type semiconductor layer in the gate region;
removing an exposed portion of the P-type semiconductor layer by in-situ etching with a corrosive gas, by using the patterned mask layer as a mask; and
activating P-type dopant ions in the P-type semiconductor layer.

2. The method for manufacturing the semiconductor structure according to claim 1, wherein the in-situ etching comprises:
a step of forming the patterned mask layer and a step of etching, which are performed in one reaction chamber, or in different chambers of one vacuum interconnect device.

3. The method for manufacturing the semiconductor structure according to claim 1, wherein a material of the P-type semiconductor layer is GaN, removing the exposed portion of the P-type semiconductor layer by in-situ etching is performed at a temperature higher than 300° C., and the corrosive gas comprises H₂ and/or NH₃, a mixture of Cl₂ and N₂, or HCl.

4. The method for manufacturing the semiconductor structure according to claim 3, wherein removing the exposed portion of the P-type semiconductor layer by in-situ etching is performed at a temperature higher than 700° C.

5. The method for manufacturing the semiconductor structure according to claim 1, wherein after activating P-type doped ions in the P-type semiconductor layer, the method further comprises:
growing an N-type semiconductor layer on two sides of the P-type semiconductor layer and on the heterojunction structure by using the patterned mask layer as a mask.

6. The method for manufacturing the semiconductor structure according to claim 5, wherein a material of the N-type semiconductor layer is GaN or AlGaN.

7. The method for manufacturing the semiconductor structure according to claim 1, wherein after activating P-type dopant ions in the P-type semiconductor layer, the method further comprises:
growing an N-type semiconductor layer on top of the patterned mask layer, on two sides of the patterned mask layer and the P-type semiconductor layer, and on the heterojunction structure.

8. The method for manufacturing the semiconductor structure according to claim 7, wherein a material of the N-type semiconductor layer is AlN.

9. The method for manufacturing the semiconductor structure according to claim 3, wherein a material of the heterojunction structure adjacent to the P-type semiconductor layer is AlGaN.

10. The method for manufacturing the semiconductor structure according to claim 1, wherein after removing the exposed portion of the P-type semiconductor layer by in-situ etching, the method further comprises:
performing a step of cooling down; and
stopping supplying the corrosive gas during the step of cooling down.

11. The method for manufacturing the semiconductor structure according to claim 10, wherein in the step of cooling down, supplying the corrosive gas is stopped at a temperature greater than or equal to 600° C.

12. The method for manufacturing the semiconductor structure according to claim 10, wherein in the step of cooling down, an inert protective gas is provided.

13. The method for manufacturing the semiconductor structure according to claim 1, wherein P-type dopant ions in the P-type semiconductor layer is activated by annealing at a temperature greater than 500° C.

14. The method for manufacturing the semiconductor structure according to claim 1, wherein a material of the patterned mask layer is silicon dioxide, silicon nitride or silicon oxynitride.

15. The method for manufacturing the semiconductor structure according to claim 1, further comprising:
forming a source electrode on a source region,
forming a drain electrode on a drain region, and
forming a gate electrode on the activated P-type semiconductor layer.

16. The method for manufacturing the semiconductor structure according to claim 5, further comprising:
removing the patterned mask layer to expose the P-type semiconductor layer.

17. The method for manufacturing the semiconductor structure according to claim 5, further comprising:
removing the patterned mask layer to expose the P-type semiconductor layer by wet etching.

18. The method for manufacturing the semiconductor structure according to claim 7, further comprising:
removing the patterned mask layer and a portion of the N-type semiconductor layer on the patterned mask layer to expose the P-type semiconductor layer.

19. The method for manufacturing the semiconductor structure according to claim 7, further comprising:
removing the patterned mask layer and a portion of the N-type semiconductor layer on the patterned mask layer to expose the P-type semiconductor layer by dry etching.
